(19) United States
(12) Patent Application Publication
(10) Pub. No.: US 2003/0108810 A1
(43) Pub. Date: Jun. 12, 2003

(54) Deodorizing agent for sulfur- or nitrogen-containing salt photoinitiators

(76) Inventors: Sue Ellen Williamson, Chamblee, GA (US); Joann Arceneaux, Marietta, GA (US)

Correspondence Address: WENDEROTH, LIND & PONACK, L.L.P., 2033 K STREET N. W., SUITE 800, WASHINGTON, DC, 20006-1021, US

(21) Appl. No.: 09/933,910

(22) Filed: Aug. 22, 2001

(51) Int. Cl. G03F 7/004

(52) U.S. Cl. 430/270.1; 430/921

(57) ABSTRACT

Cationic initiator compositions for initiating cationic polymerization which contain a sulfur- or nitrogen-containing initiator, such as a sulfonium salt photoinitiator, and a deodorizing agent are disclosed. The deodorizing agent reduces undesirable odors, such as the organosulfur/mercaptan/thio odor generated by the decomposition of the sulfonium salt initiator upon initiation. The deodorizing agent may be a free radical inhibitor or phenolic compound such as methylether of hydroquinone, toluhydroquinone and hydroquinone. Processes for making and using the composition are also disclosed. The composition has applications in the coating, photoresist, adhesion, graphic arts and sealant arts among others.

The present invention relates to sulfur- or nitrogen-containing salt photoinitiator compositions containing a deodorizing agent which reduces undesirable odors such as the organosulfur/mercaptan/thio odor produced from the photodecomposition of sulfonium salt initiators. The deodorizing agent may be a free radical inhibitor or a phenolic compound such as, for example, hydroquinone, toluhydroquinone or methylhydroquinone. The present invention also relates to photopolymerizable compositions, processes for forming the compositions and for its various applications in the coating, photoresist, adhesive, graphics and sealant arts.

### BACKGROUND OF THE INVENTION

There has been a long felt need to attain highly durable coatings and effective procedures which allow for the coating of substrates at high production rates while minimizing potential costly environmental hazards. The use of aromatic sulfonium salt complexes as photoinitiators in photopolymerizable formulations providing rapidly polymerized resin coatings have been disclosed in, for example, U.S. Pat. Nos. 3,708,296, 3,794,576, 4,058,400 and 4,058,401. The sulfonium salt photoinitiator releases cations upon exposure to actinic radiation which, in turn, initiates the cationic polymerization or crosslinking of one or more materials containing polymerizable or crosslinkable groups. These sulfonium salt photopolymerizable compositions afford many desirable properties and very satisfactory products. However, these compositions tend to emit an undesirable odor, characteristic of mercaptan and other organosulfur compounds, generated from the photodecomposition of the sulfonium salt initiator. The industry has therefore been seeking novel sulfonium salt compositions and processes which would not require the extensive handling and high equipment cost of prior compositions.

In U.S. Pat. Nos. 4,250,230 and 4,306,953, sulfonium salt photopolymerizable compositions are disclosed which include a scavenger or stable free radical to reduce the sulfur odor emitted by the photodecomposed sulfonium salt. However, the disclosed additives provide a negative effect on the cure rates, adhesion and MEK rub resistance.

U.S. Pat. No. 4,324,679 discloses sulfonium salt photopolymerizable systems containing an aromatic radical additive which provides odor reduction. However, there is no disclosure of phenolic compounds or free radical inhibitors as the additive, nor does U.S. Pat. No. 4,324,679 disclose the effects on the additive on any of the physical properties of the curing composition.

Therefore, none of the prior art teaches nitrogen- or sulfur-containing photoinitiator compositions comprising a deodorizing agent in the form of a phenolic compound or free radical inhibitor which does not severely compromise the curing rates and other physical properties of the composition.

### BRIEF SUMMARY OF THE INVENTION

It is an object of the present invention to provide a novel cationic photoinitiator composition for initiating cationic polymerization comprising a sulfur- or nitrogen-containing photoinitiator, such as, for example, a sulfonium salt photoinitiator, and a deodorizing agent which reduces the odor of the photoinitiator composition upon initiation due to the decomposition of the a sulfur- or nitrogen-containing photoinitiator.

It is also an object of the present invention to provide a curable cationic polymerizable composition comprising a sulfur- or nitrogen-containing polymerizable material and a deodorizing agent; wherein the deodorizing agent reduces the undesirable sulfur- or nitrogen-compound odor of the composition generated upon the photodecomposition of the sulfur- or nitrogen-containing photoinitiator during initiation. In a preferred embodiment, the photoinitiator is a sulfonium salt photoinitiator whereas the deodorizing agent is a phenolic or free radical inhibitor which does not compromise the curing rate, MEK rub resistance and other physical properties of the composition.

A further object of the present invention is to provide a process for curing a cationic polymerizable composition containing a sulfur- or nitrogen-containing photoinitiator, such as, for example, a sulfonium salt photoinitiator, and polymerizable material which comprises adding a deodorizing agent to said composition in order to reduce the odor upon curing generated by the photodecomposition of the sulfur- or nitrogen-containing photoinitiator. A preferred initiator is a sulfonium salt photoinitiator and a preferred deodorizing agent is a free radical inhibitor or phenolic compound such as, for example, a quinone or a quinone derivative. This process can be used in, for example, coating, photoresist, adhesive, graphics, and sealant applications.

Another object of the present invention is to provide positive- and negative-acting acid sensitive photoresist compositions comprising a photoactive sulfur- or nitrogen-containing compound such as, for example, a photoactive sulfonium salt, a resin binder and a deodorizing agent which reduces the odor of the compound upon initiation.

A further object of the present invention is to provide an article of manufacture having at least one surface wherein said surface comprises a coating layer of a positive- or negative-acting acid sensitive photoresist composition comprising a photoactive sulfur- or nitrogen-containing compound such as, for example, photoactive sulfonium salt, a resin binder and a deodorizing agent; wherein said deodorizing agent reduces the odor of the compound upon cure.

A final object of the present invention is to provide a process for preparing an acid sensitive photoresist composition containing a photoactive sulfur- or nitrogen-containing compound such as, for example, photoactive sulfonium salt and a resin binder; wherein the improvement comprises adding a deodorizing agent to said acid sensitive photoresist composition in order to reduce the odor attained upon curing due to the photo-decomposition of the sulfonium salt photoinitiator.

### DETAILED DESCRIPTION OF THE INVENTION

The present invention relates to cationic photoinitiator compositions for initiating cationic polymerization comprising a sulfur- or nitrogen-containing photoinitiator and a deodorizing agent; wherein the deodorizing agent reduces the odor of the photoinitiator composition upon initiation due to the photodecomposition of the nitrogen or sulfur-containing-compound initiator such as, for example, a sulfonium salt photoinitiator.

Particularly, formulations containing sulfonium salt photoinitiators develop an unpleasant organosulfur/mercaptan/thio odor upon cure. Applicant has found that the odor generated by these formulations may be reduced upon addition of certain additives such as phenolic compounds or free radical inhibitors. These photoinitiator compositions have applications in the coating, photoresist, adhesion, ink and sealant arts.

In a preferred embodiment, the sulfur-containing deodorizing agent is a sulfonium salt photoinitiator, whereas the deodorizing agent is a free radical inhibitor or phenolic compound, such as a quinone or a quinone derivative, which does not compromise the curing rate, MEK resistance and/or other physical properties of the composition.

Applicant has found that formulations comprising epoxy monomers, a sulfonium salt photoinitiator and phenolic compounds such as methylhydroquinone (MEHQ), have remarkably little odor after cure when compared to similar epoxy formulations without the added phenolic compounds. Addition of phenolic inhibitors such as MEHQ produce little or no color development over several weeks at room temperature, nor do they affect formulation cure speeds or the cured properties. Thus the addition of a deodorizing agent such as a phenolic inhibitor as, for example, MEHQ, can produce a unique and improved product which distinguishes the initiator of the present invention from initiators of the prior art. Reduction of the undesirable organosulfur/mercaptan/thio odor produced by sulfonium salt photoinitiators during and after cure would be invaluable in the production scale of curing compounds.

Among the additives, free radical inhibitors and phenolic inhibitors which can serve as the deodorizing agent in the present invention are quinones and their derivatives. These quinone derivatives have the following structure:

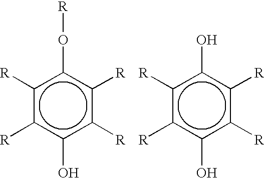

wherein the “R” substituents may be, independently, for example, C1-C20 linear or branched aliphatic alkl groups, or cycloaliphatic groups or aromatic groups, which may eventually themselves be substituted with functional groups such as ester, hydroxy, nitrile, carboxy, halogen etc.

Among the quinone derivatives tested were those in the following table:

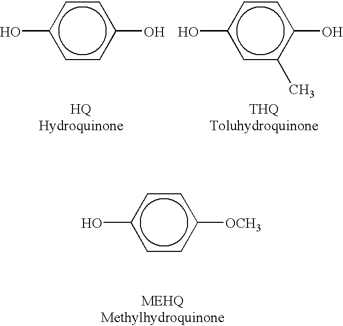

In particular, methylhydroquinone (MEHQ), when added to sulfonium salt initiator solutions, produces little or no color development and furthermore is very easy to incorporate in initiator solutions. In fact, addition of up to 1500 ppm of MEHQ (based on the total curable composition) to the sulfonium salt initiator does not affect formulation cure speeds or cured properties. It has been found that the addition of MEHQ to the sulfonium salt initiator formulation results in an unexpected improvement and reduction in the organosulfur/mercaptan/thio odor released upon the photodecomposition of the sulfonium salt initiator which develops during cure. Consequently, curing at large scales will amplify this effect.

Among the photoinitiators which may be used are sulfonium salts selected from among dialkylphenacylsulfonium salts, dialkyl-4-hydroxyphenylsulfonium salts, bis-p-diphenylsulfoniumphenylsulfide salts, diphenylphenylthiophenyl sulfonium salts, benzylsulfonium salts, benzyltetramethylene sulfonium salts, benzyl(p-hydroxyphenyl)methyl-sulfonium salts, triarylsulfonium salts, triphenylsulfonium salts and mixtures thereof. The sulfonium salt initiators may contain arylsulfonium salts as major components with possibly other sulfonium salts present in low concentrations as shown below.

Examples of these sulfonium salt photoinitiators include the following dialkylphenacylsulfonium salts; wherein if several R's are indicated, the R's may be the same or different; and wherein the X⁻ may be any anion as described below:

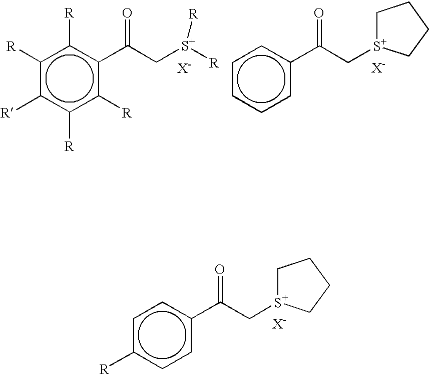

Other examples of the sulfonium salt include the following dialkyl-4-hydroxyphenylsulfonium salts:

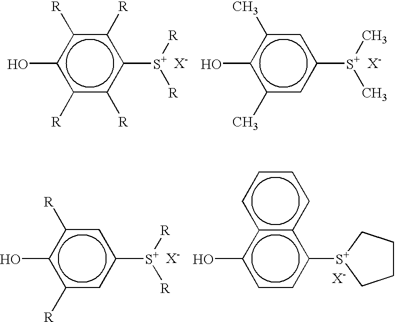

Among preferred benzylsulfonium salts are the following:

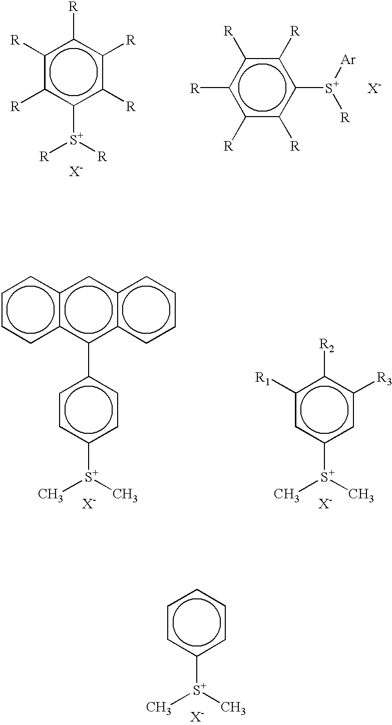

Other preferred benzyl salts include the following:

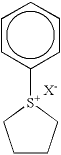

### benzyltetramethylenesulfonium salts

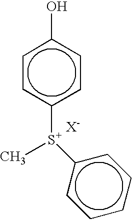

### benzyl(p-hydroxyphenyl)methyl-sulfonium salts

Also, the sulfonium salt initiator may be selected from the following:

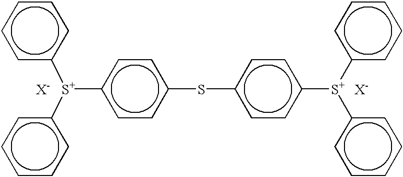

### bis-p-diphenylsulfoniumphenylsulfide salts

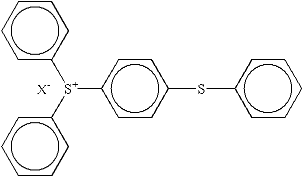

### diphenylphenylthiophenylsulfonium salts

Regarding the triarylsulfonium salts, these may be commercial initiators but in the present invention the aryl group can be any aromatic group such as phenyl, naphthyl, cumyl, and toulyl, etc.

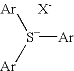

### Triarylsulfonium salts

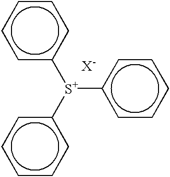

### Triphenylsulfonium salts

Many commercial sulfonium salt initiators typically contain a blend of the following two molecules (plus small amounts of other compounds):

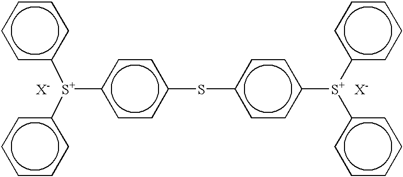

### Bis-p-diphenylsulfoniumphenylsulfoniumphenylsulfide salt

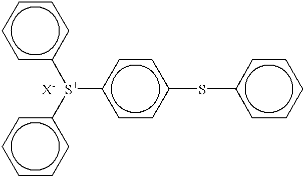

### Diphenylphenylthiophenylsulfonium salt

For example, commercial “Triarylsulfonium Hexafluorophosphate” initiators contain the following major components although other sulfonium salts may be present in low concentrations:

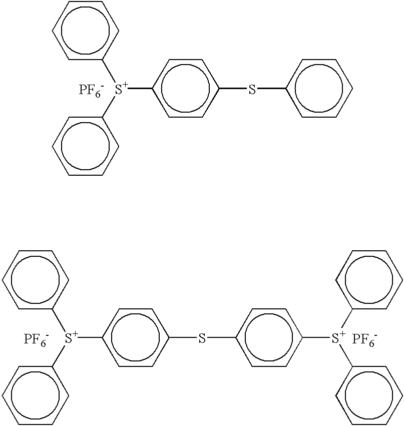

### “Mixed Triarylsulfonium Hexafluorophosphate”

Besides those discussed above, other triarylsulfonium salts which can be used as initiators are:

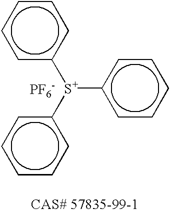

### Triphenylsulfonium Hexafluorophosphate

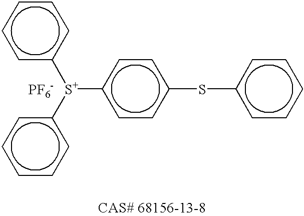

### Diphenylphenylthiophenylsulfonium Hexafluorophosphate

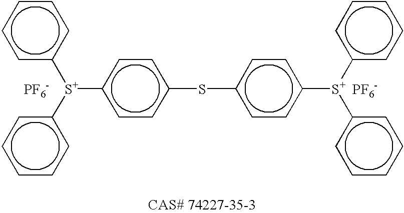

Bis-p-diphenylsulfoniumphenylsulfoniumphenylsulfide Hexafluorophosphate

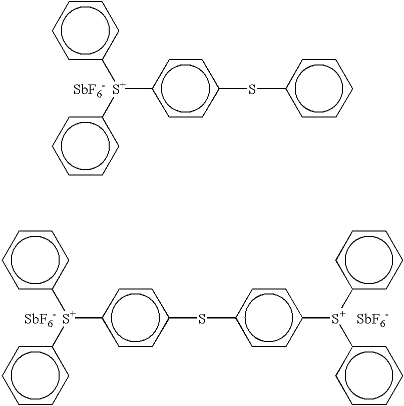

### “Triarylsulfonium Hexafluoroantimonate”

A number of other sulfonium compounds (cations) may also be present in small amounts. The distribution and products are a result of the synthetic process used to make the sulfonium salts. (See e.g., U.S. Pat. No. 2,807,648 for a discussion of the process of making triaryl sulfonium compounds).

The counterions (anions) can be selected from a large number of organic and inorganic anions. Counterions (anions) may be non-nucleophillic “complex metal halide anions” such as BF₄—, PF₆—, AsF₆—, SbF₆— or anions of strong protonic acids such as ClO₄—, CF₃SO₃—, FSO₃—, CH₃SO₃—, or C₄F₉SO₃—. Counteranions may also include fluoroorganic imide or methide anions as are described in U.S. Pat. No. 5,554,664. The counterion may be any other non-nucleophillic anion, such as borates or gallates, such as are B(C₆F₅)₄—, Ga(C₆F₅)₄—, B(C₆H₅)₄—, B[C₆H₂(CF₃)₃]₄— or B[C₆H₃(CF₃)₂]₄—.

The cationic photoinitiator composition for initiating cationic polymerization may further comprise a solvent, wherein the solvent may be, for example, propylene carbonate, butyrolactone, tetrahydrofuran, N,N-dimethylformamide, alcohols such as aliphatic and aromatic alcohols, ethers, aromatic hydrocarbons, cyclic ethers, aliphatic hydrocarbons, benzene, toluene, dioxane, tetrahydropyran, dimethoxyethane, n-hexane, cyclohexane, acetone, acetonitrile or mixtures thereof

Among the preferred solvents are propylene carbonate and γ-butyrolactone:

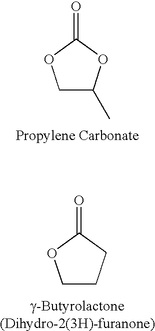

Among the polymerizable materials which can be used with the present invention are epoxy resins, including cycloaliphatic epoxides and diepoxides, epoxy oligomers and diglycidyl ethers, acrylate oligomers and mixtures thereof Also, the polymerizable material can further be chosen from among glycidyl ethers, polyorganosiloxanes, epoxypolyorganosiloxanes, vinyloxy substituted polyorganosiloxanes, oxetanes and other cyclic ethers, vinyl ethers, alpha olefins, dienes, butadienes, isoprene, natural oils, castor oil, linseed oil, styrenes, alpha methyl styrenes, vinyl toluenes, phenyl vinyl ethers, N-vinyl carbazole, N-vinyl pyrrolidinones, acid curable materials and mixtures thereof

Furthermore, the polymerizable materials which can be used with the present invention include glycidyl ether moieties selected from diglycidyl ethers of bisphenol A, diglycidyl ethers of bisphenol F, epoxy phenol novolacs, epoxy cresol novolacs, bisphenol A epoxy novolacs, tetraglycidyl ether of tetrakis(4-hydroxyphenyl)ethane, glycidyl ethers of the condensation product of dicyclopentadiene and phenol, triglycidyl ether of tris(hydroxyphenyl)methane and mixtures thereof

Epoxy resins which may be used with the present invention include:

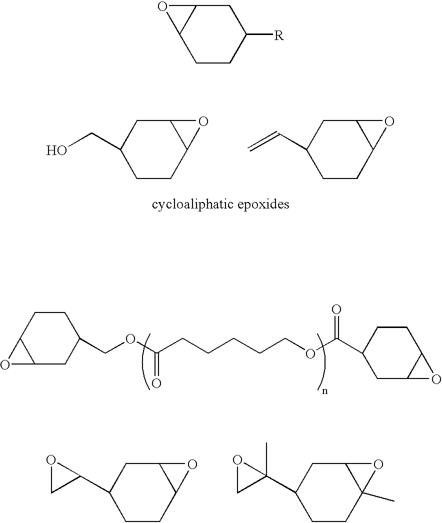

### cycloaliphatic diepoxides

For example, a preferred cycloaliphatic diepoxide which can be used with the present invention is:

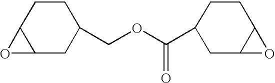

### 3,4-Epoxycyclohexylmethyl-3,4-epoxy-cyclohexane carboxylate or “EEC”

Examples of glycidyl ether monomers which can be used with the present invention are:

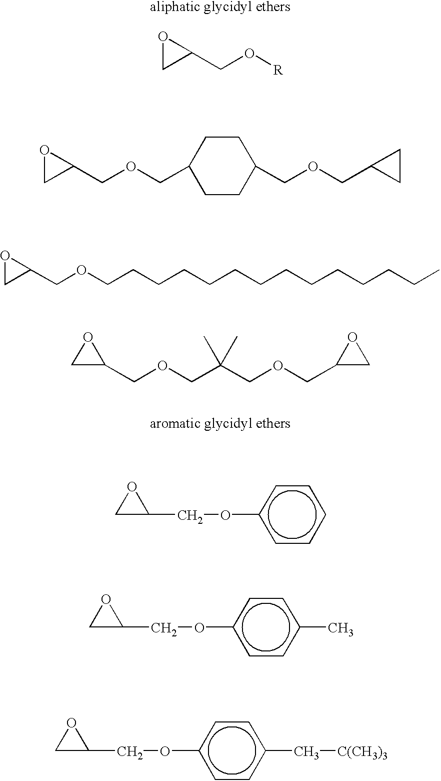

Aromatic glycidyl ether resins that are suitable for the present invention are based on the following structure where R can be almost any aliphatic or aromatic group:

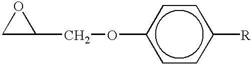

Examples of specific aromatic glycidyl ether resins which can be used in the present invention include:

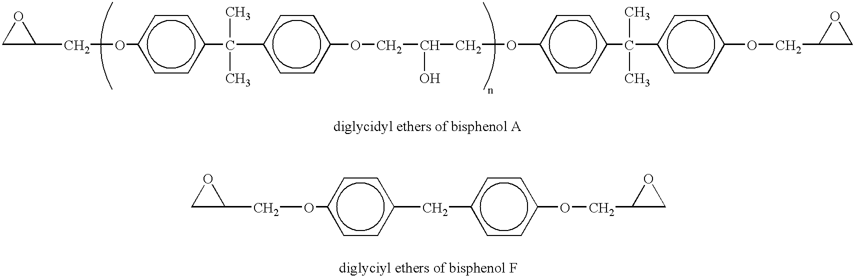

Among the epoxy novolacs that may be used in the present invention are:

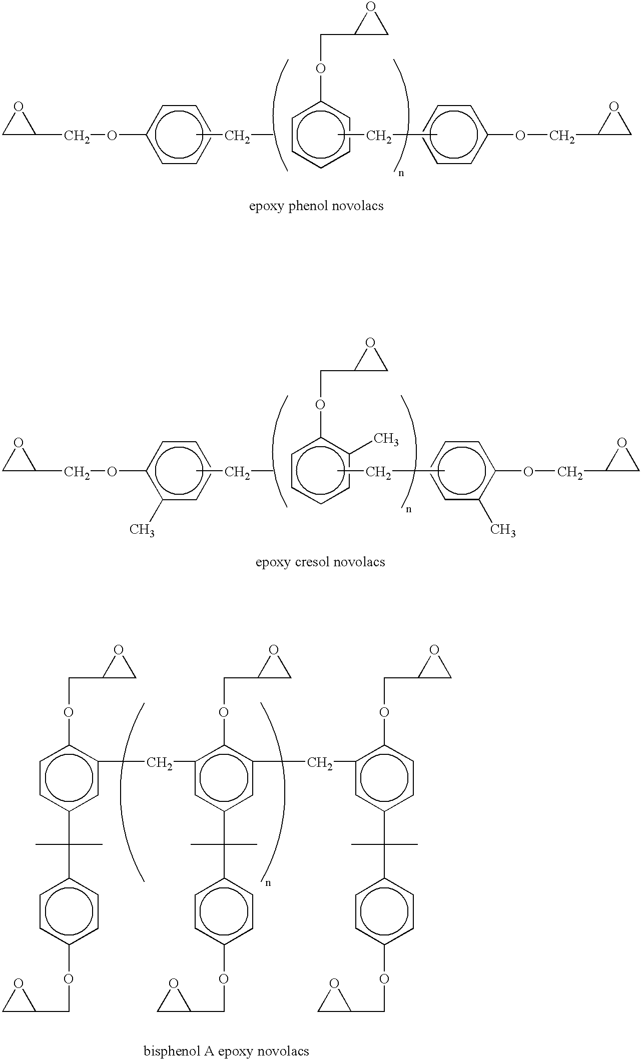

Also, the following glycidyl ethers may be used in the present invention:

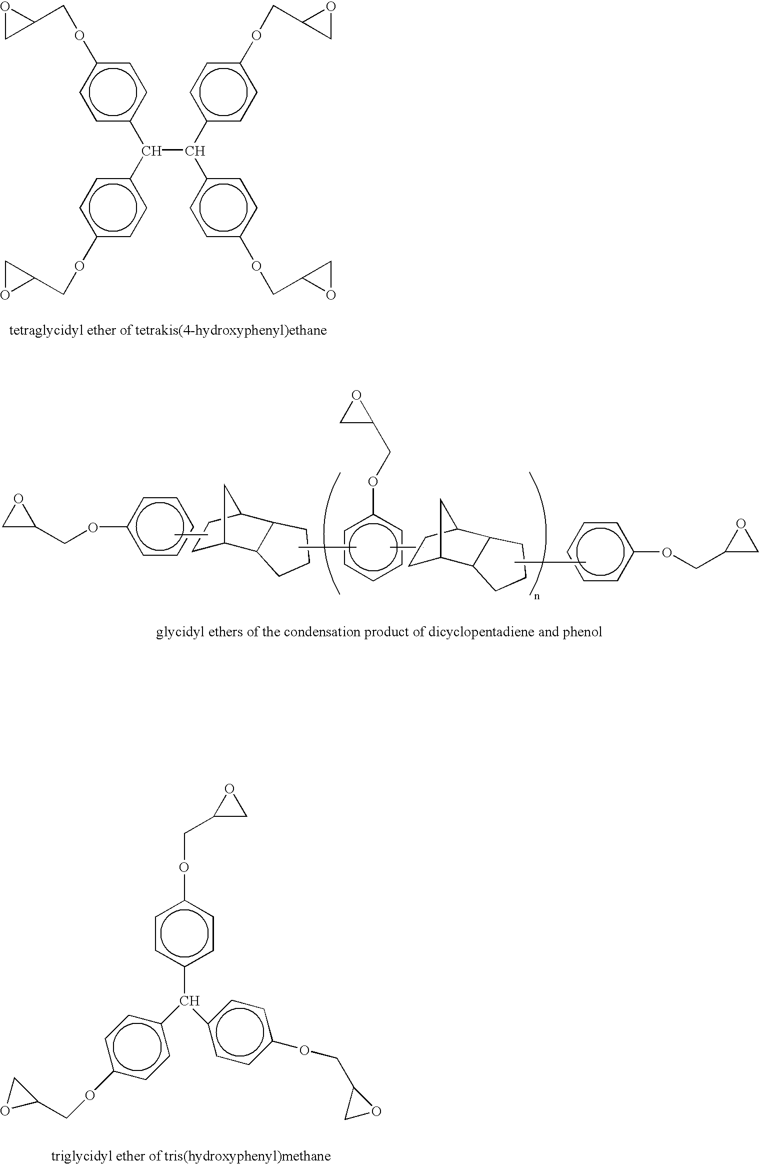

The following polyorganosiloxanes may also be used as the polymerizable material in the present invention, wherein R is typically a methyl group, but instead can also be ethyl, phenyl, or any other aliphatic group. In other instances, R could also be an epoxy or other reactive group. If several R's are indicated, the R's may be the same or different.

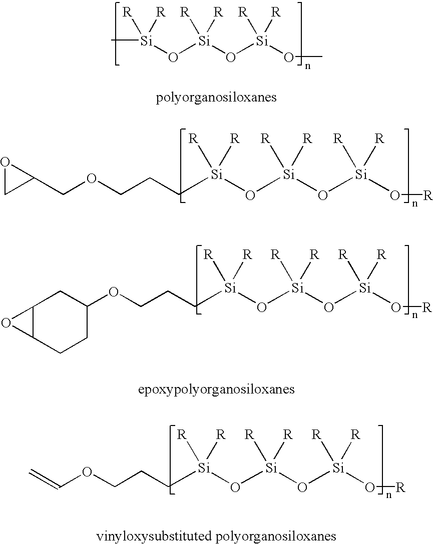

Other examples of the polymerizable material which may used in the present invention are the following oxetanes, cyclic ethers and vinyl ethers.

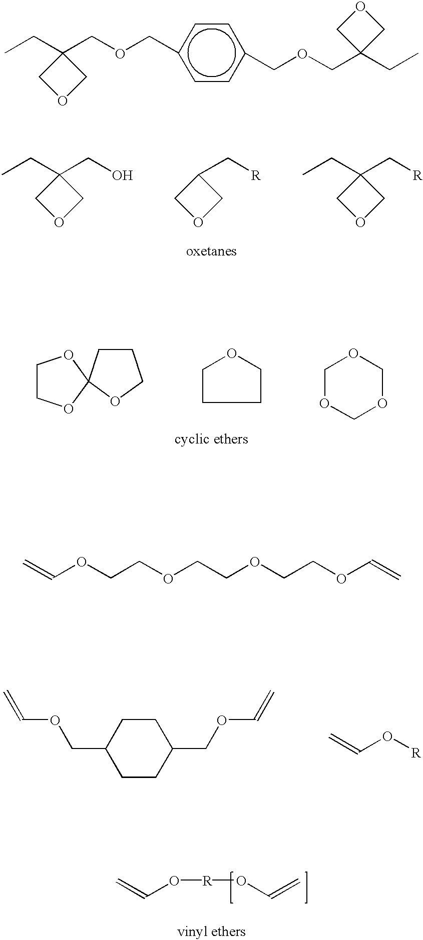

Applicants have also invented curable cationic polymerizable compositions comprising a sulfur- or nitrogen-containing photoinitiator, polymerizable material, and a deodorizing agent; wherein the deodorizing agent reduces the sulfur- or nitrogen-compound odor of the composition upon initiation.

This curable composition can be cured by radiation or irradiation such as, for example, actinic, ultraviolet, visible light, infrared, microwaves, radio, ionizing, alpha, beta, gamma, X-rays or electron beams.

The polymerizable material can be selected from among epoxy monomers, epoxy oligomers, acrylate oligomers and mixtures thereof, including all of the polymerizable materials described earlier.

For example, the polymerizable material can be chosen from among aromatic epoxy resins, aliphatic epoxy resins, cycloaliphatic epoxide and diepoxide resins, glycidyl ethers, polyorganosiloxanes, epoxypolyorganosiloxanes, vinyloxysubstituted polyorganosiloxanes, oxetanes and other cyclic ethers, vinyl ethers, alpha olefins, dienes, butadienes, isoprene, natural oils, castor oil, linseed oil, styrenes, alpha methyl styrenes, vinyl toluenes, phenyl vinyl ethers, N-vinyl carbazole, N-vinyl pyrrolidinones, acid curable materials and mixtures thereof.

Furthermore, the cationic polymerizable composition can comprise polymerizable material such as epoxy resin moieties selected from among diglycidyl ethers of bisphenol A, diglycidyl ethers of bisphenol F, epoxy phenol novolacs, epoxy cresol novolacs, bisphenol A epoxy novolacs, tetraglycidyl ether of tetrakis(4-hydroxyphenyl)ethane, glycidyl ethers of the condensation product of dicyclopentadiene and phenol, triglycidyl ether of tris(hydroxyphenyl)methane and mixtures thereof.

The deodorizing agent can be a free radical or phenolic compound. The phenolic compound can be a quinone or a quinone derivative such as hydroquinone, toluhydroquinone, or methylhydroquinone.

Preferred sulfur-containing photoinitiators are sulfonium salt photoinitiators containing the sulfonium salts discussed above. For example, the sulfonium salt can be selected from, for example, dialkylphenacylsulfonium salts, dialkyl-4-hydroxyphenylsulfonium salts, bis-p-diphenylsulfoniumphenylsulfide salts, diphenylphenylthiophenyl sulfonium salts, benzylsulfonium salts, benzyltetramethylene sulfonium salts, benzyl(p-hydroxyphenyl)methyl-sulfonium salts, triarylsulfonium salts, triphenylsulfonium salts and mixtures thereof.

The counterions (anions) can be selected from a large number of organic and inorganic anions, as described previously. Counterions (anions) may be non-nucleophillic “complex metal halide anions” such as BF₄—, PF₆—, AsF₆—, SbF₆— or anions of strong protonic acids such as ClO₄—, CF₃SO₃—, FSO₃—, CH₃SO₃— or C₄F₉SO₃—. Counteranions may also include fluoroorganic imide or methide anions as are described in U.S. Pat. No. 5,554,664. The counterion may be any other non-nucleophillic anion, such as borates or gallates such as are B(C₆F₅)₄—, Ga(C₆F₅)₄—, B(C₆H₅)₄—, B[C₆H₂(CF₃)₃]₄— or B[C₆H₃(CF₃)₂]₄—.

In addition, the curable composition may further comprise a solvent selected from among propylene carbonate, butyrolactone, tetrahydrofuran, N,N-dimethylformamide, alcohols, ethers, aromatic hydrocarbons, cyclic ethers, aliphatic hydrocarbons, benzene, toluene, dioxane, tetrahydropyran, dimethoxyethane, n-hexane, cyclohexane, acetone, acetonitrile and mixtures thereof.

The curable composition may further comprise a reactive diluent. This reactive diluent may be selected from among epoxides such as low viscosity epoxides, diepoxides, low viscosity alcohols, polyols such as polycaprolactone triols, phenols, vinyl ethers, vinyl monomers, cyclic ethers, tetrahydrofuran, tetrahydropyran, cyclic carbonates, cyclic esters, butyrolactone, propylene carbonate, acrylates, methacrylates, aliphatic monohydric alcohols and compounds containing more than one of the listed functional groups on one molecule.

Also, a process for curing a cationic polymerizable composition was found for a composition containing a sulfonium salt photoinitiator in polymerizable material; wherein the improvement comprises adding a deodorizing agent to the composition in order to reduce the odor upon curing. The process includes the cationic polymerizable composition being cured by radiation or irradiation such as, for example, actinic, ultraviolet, visible light, infrared, microwaves, radio, ionizing, alpha, beta, gamma, X-rays or electron beams.

The process may comprise polymerizable material, a deodorizing agent, a sulfonium salt photoinitiator and a reactive diluent selected from the same polymerizable materials, deodorizing agents, sulfonium salt photoinitiators and reactive diluents discussed previously in forming the cationic photoinitiator composition and the curable cationic polymerizable composition.

The instant photoinitiator composition is also applicable in the photoresist art. Photoresists are photosensitive films used to transfer images to a substrate to form positive or negative images. A photoresist is coated onto a substrate followed by exposure of the coating through a patterned photomask to an activating radiation source. A latent image pattern is defined on the photoresist coating due to opaque and transparent areas to the activating radiation in the photomask. A relief image is provided by developing the latent image pattern in the resist coating.

Positive acting- or negative acting-acid sensitive photoresist compositions were found which comprise a photoactive sulfur- or nitrogen-containing compound such as, for example, a photactive sulfonium salt, a resin binder and a deodorizing agent; wherein the deodorizing agent may be a phenolic compound or a free radical inhibitor which reduces or eliminates the organosulfur/mercaptan/thio odor generated upon the photodecomposition of the sulfonium salt photoinitiator upon initiation. This composition may be a chemically amplified positive-acting photoresist or may be a negative-acting photoresist composition.

The resin binders for the positive acting- or negative acting-photoresist composition may be selected from among novolac resins, block novolac resins, phenolic compounds, phenolic resins, vinylphenols, polyvinylphenols, partially hydrogenated derivatives of novolacs, partially hydrogenated derivatives of phenolic compounds, copolymers containing phenolic moieties, copolymers containing aliphatic cyclic alcohol moieties, bishydroxymethylated compounds comprising polar functional groups, compounds comprising hydroxyl groups, compounds comprising carboxylate groups, imide polymers, styrenes, styrene copolymers, vinylic polymers, polyolefins and mixtures thereof

The positive- or negative-acid sensitive photoresist composition may further include a crosslinker. The crosslinker can be selected from among amines, melamines, glycolurils, benzoguanamines, ureas, melamine-formaldehyde resins and mixtures thereof

The positive acting- or negative acting-acid sensitive photoresist composition can further include additives. These additives can be selected from the group consisting of actinic dyes, contrast dyes, anti-striation agents, plasticizers, speed enhancers and photosensitizer compounds.

The positive acting- or negative acting-acid sensitive photoresist composition can be cured by radiation or irradiation selected from among actinic, ultraviolet, visible light, infrared, microwaves, radio, ionizing, alpha, beta, gamma, X-rays and electron beams.

The deodorizing agent can be a free radical inhibitor or a phenolic compound. The phenolic compound may be a quinone or a quinone derivative such as, for example, hydroquinone, toluhydroquinone and methylhydroquinone.

The photoactive sulfonium salt may be a sulfonium salt. The sulfonium salt can be chosen from among dialkylphenacylsulfonium salts, dialkyl-4-hydroxyphenylsulfonium salts, bis-p-diphenylsulfoniumphenylsulfide salts, diphenylphenylthiophenyl sulfonium-salts, benzylsulfonium salts, benzyltetramethylene sulfonium salts, benzyl(p-hydroxyphenyl)methyl-sulfonium salts, triarylsulfonium salts, triphenylsulfonium salts and mixtures thereof

The positive acting- or negative acting-acid sensitive photoresist composition may further include a solvent wherein said solvent may be selected from propylene carbonate, butyrolactone, tetrahydrofuran, N,N-dimethylformamide, alcohols such as aliphatic and aromatic alcohols, ethers, aromatic hydrocarbons, cyclic ethers, aliphatic hydrocarbons, benzene toluene, dioxane, tetrahydropyran, dimethoxyethane, n-hexane, cyclohexane, acetone, acetonitrile and mixtures thereof.

The acid sensitive photoresist composition can be applied as a coating layer of an article of manufacture having at least one surface. Conventional methods known in the art such as coating, extrusion and lamination may be used to apply the photoresist layer on to the article surface.

In addition, the present invention includes a process for preparing the positive- or negative acting-acid sensitive photoresist compositions containing a photoactive sulfur- or nitrogen-containing compound such as, for example, a photoactive sulfonium salt in the resin binder; wherein the improvement comprises adding a deodorizing agent to the acid sensitive photoresist composition in order to reduce the odor generated by decomposition of the sulfonium salt photoinitiator upon curing.

The following examples further illustrate the best mode contemplated by the inventors for the practice of their invention. The examples are to be construed as illustrative of and not in limitation of the invention.

With respect to the materials employed in the following working examples, the following information is provided:

| | Commercial | |
|---|---|---|
| Abbreviation | Source | Composition |
| Cyracure UVI-6990, | Union | 50% Mixed triarylsulfonium salts |
| UVI-6990 | Carbide | having PF6- as counterion in 50% |
| | | Propylene carbonate |
| FX-512 | 3M Product | 45-55% Mixed triarylsulfonium |
| | | salts having PF6- as counterion in |
| | | 40% γ-Butyrolactone |
| Uvacure 1590 | UCB | 50% Mixed triarylsulfonium salts |
| | | having PF6- as counterion in 50% |
| | | Propylene carbonate |
| SarCat CD 1011 | Sartomer | 50% Mixed triarylsulfonium salts |
| | | having PF6- as counterion in 50% |
| | | Propylene carbonate |
| Cyracure UVI-6974, | Union | 50% Mixed triarylsulfonium salts |
| UVI-6974 | Carbide | having SbF6- as counterion in 50% |
| | | Propylene carbonate |
| SarCat CD 1010 | Sartomer | 50% Mixed triarylsulfonium salts |
| | | having SbF6- as counterion in 50% |
| | | Propylene carbonate |
| Tone 301 | Union | Polycaprolactone triol |
| | Carbide | |
| Silwet L-7602 | OSi | Surfactant |
| | Specialties | |
| EEC | UCB | 3,4-Epoxycyclohexylmethyl-3,4- |
| | | epoxy-cyclohexane carboxylate |
| MEHQ | Aldrich | Methylhydroquinone |
| HQ | Aldrich | Hydroquinone |
| THQ | Aldrich | Toluhydroquinone |

Applicants tested a curable formulation containing EEC, a triaryl sulfonium hexafluorophosphate salt initiator in propylene carbonate (50 % solids) and 500 ppm MEHQ and proved that the organosulfur/mercaptan/thio odor produced by the sulfonium salt photoinitiator was reduced during and after cure.

Testing was performed on several phenolic compound/sulfonium salt initiator systems, especially hydroquinone/sulfonium salt mixtures. In particular, extensive studies were performed on MEHQ/triarylsulfonium salt systems. The effect of adding MEHQ to the system regarding cure speed, properties, and odor development were examined. In addition to MEHQ, other hydroquinone phenolic inhibitors such as toluhydroquinone and hydroquinone were evaluated but were not as desirable for some applications since they cause significant darkening of the solutions containing sulfonium salt initiator.

MEHQ added to sulfonium salt initiator solutions produced little to no color development during the time scale of the evaluation (seven months at room temperature), and is the easiest of the three additives tested to incorporate into the initiator solutions.

Moreover, addition of 1500 or more ppm MEHQ (based on the total formulation) to the sulfonium salt initiator does not affect formulation cure speeds or cured properties.

On these laboratory scales, MEHQ addition results in a noticeable improvement in the organosulfur/mercaptan/thio odor which develops during cure. Curing on a production scale will, of course, amplify this deodorizing effect. Thus, addition of deodorizing agent MEHQ produces a unique and improved product which distinguishes the present invention's initiator composition from conventional initiators. In addition, since the odor reduction mechanism seems to be dependent on a sulfonium salt photoproduct/MEHQ interaction, addition of MEHQ to the initiator package assures that the ratio of the sulfonium salt initiator to MEHQ will remain constant.

Although it is difficult to predict the amount of initiator that will be required for a particular application, most published starting point formulations recommend using between 2 and 5% sulfonium salt initiator. The following table lists the amount of odor inhibitor which should be added to the initiator to achieve 500 ppm inhibitor in a finished formulation.

TABLE A
Amount Odor Inhibitor Required to Achieve
500 ppm in Total Formulation

| Formulation % | % Inhibitor in | ppm Inhibitor in |
|---|---|---|
| Initiator | Initiator | Formulation |
| 0.5% | 10% | 500 |
| 1.0% | 5% | 500 |
| 2.0% | 2.5% | 500 |
| 5% | 1% | 500 |
| 10% | 0.5% | 500 |

Among the sulfonium salt initiators and inhibitors tested were MEHQ, hydroquinone and toluhydroquinone.

Triaryl sulfonium salt initiators tested include the following:

| Initiator | Counterion | % solids | Solvent |
|---|---|---|---|
| Union Carbide UVI- | PF₆⁻ | 50% | Propylene Carbonate |
| 6990 | | | |
| 3M FX-512 | PF₆⁻ | 60% | γ-Butyrolactone |
| UCB Uvacure 1590 | PF₆⁻ | 50% | Propylene Carbonate |
| Union Carbide UVI- | SbF₆⁻ | 50% | Propylene Carbonate |
| 6974 | | | |

Preferred solvents for the initiators are propylene carbonate or γ-butyrolactone.

Solubility of MEHQ/Hydroquinone/Toluhydroquinone in Initiator Solutions

MEHQ was found to be very soluble in initiator solutions, especially those containing propylene carbonate (Union Carbide and UCB initiators). Hydroquinone and toluhydroquinone are somewhat less soluble. However, all three additives are soluble at the level needed to impart odor reduction in a formulation (˜6% or less). FX-512 is a poorer solvent for the additives than UVI 6990, either because it uses a different solvent (γ-butyrolactone) or because of the higher solids content (60% for FX 512, versus 50% in UVI 6990). Limited tests suggest that MEHQ inhibitor is equally soluble in Uvacure 1590 and in UVI 6990.

TABLE B
Amount of Additive which will Dissolve
in Triarylsulfonium Salt Composition

| | | Sulfonium | | time to |
|---|---|---|---|---|
| | Additive | Salt | % dissolved | dissolve |
| B1 | MEHQ | UVI-6990 | 11.2% | <2 hours |
| B2 | MEHQ | UVI-6990 | 32.6%* | 4 hours |
| B3 | Toluhydroquinone | UVI 6990 | 9.7%* | 3 hours |
| B4 | Hydroquinone | UVI 6990 | 8.1%* | 2 hours |
| B5 | MEHQ | Uvacure | 6.4%* | <2 hours |
| | | 1590 | | |
| B6 | MEHQ | FX 512 | 9.6%* | 1 hours |
| B7 | Toluhydroquinone | FX-512 | 11.1%* | >24 hours |
| B8 | Hydroquinone | FX 512 | 10.0%* | >24 hours |
| B9 | MEHQ | UVI-6974 | 11.5%* | <2 hours |
| B10 | Toluhydroquinone | UVI 6974 | 8.7%* | <2 hours |
| B11 | Hydroquinone | UVI-6974 | 8.9%* | 4 hours |

*Highest concentration tested.

Color Development in Initiator Solutions

No color change was observed when 6 to 10% MEHQ was added to UVI 6990, UVI 6974, Uvacure 1590 or FX 512. (The solutions were monitored for 6 months at room temperature). Toluhydroquinone produced a noticeable color change when added to UVI 6990: the solution color deepened overnight and became more red. This is undesirable for many applications. When hydroquinone was added to the initiators, a similar effect occurred, although to a lesser extent than when toluhydroquinone was added.

TABLE C
Color Change in Initiator Solution on Addition of Additive

| | | | | Color | | Color |
|---|---|---|---|---|---|---|
| | | | | after | | after |
| | | | Amount | one | Color | 7 |
| | Initiator | Additive | added | week | Rank * | months |
| C1 | UVI | None | 0% | light | 1 | light |
| | 6990 | | | yellow | | yellow |
| | | | | | | color |
| C2 | FX 512 | None | 0% | yellow | 2 | NT |
| C3 | UVI | MEHQ | 3.6% | light | 1 | pale |
| | 6990 | | | yellow | | yellow |
| C4 | UVI | MEHQ | 6.3% | light | 1 | pale |
| | 6990 | | | yellow | | yellow |
| C5 | UVI | MEHQ | 11.2% | light | 1 | pale |
| | 6990 | | | yellow | | yellow, |
| | | | | | | (some |
| | | | | | | solids) |
| C6 | UVI | MEHQ | 32.6% | light | NT | yellow |
| | 6990 | | | yellow | | (no |
| | | | | | | solids) |
| C7 | UVI | MEHQ | 6.4% | light | 1 | yellow |
| | 6990 | | | yellow | | |
| C8 | UVI | THQ | 9.7% | reddish | 5 | red- |
| | 6990 | | | | | orange |
| C9 | UVI | HQ | 8.1% | medium | 4 | dark |
| | 6990 | | | reddish | | orange |
| C10 | FX 512 | MEHQ | 9.6% | yellow | 2 | dark |
| | | | | color | | yellow |
| C11 | FX 512 | THQ | 11.1% | medium | 4 | dark |
| | | | | reddish | | orange, |
| | | | | | | (some |
| | | | | | | solids) |
| C12 | FX 512 | HQ | 10.0% | medium | 3 | very |
| | | | | yellow | | dark |
| | | | | | | orange |
| | | | | | | (some |
| | | | | | | solids) |
| C13 | UVI | MEHQ | 11.5% | light | NT | yellow |
| | 6974 | | | yellow | | |
| C14 | UVI | THQ | 8.7% | NT | NT | red- |
| | 6974 | | | | | orange |
| C15 | UVI | HQ | 8.9% | NT | NT | dark |
| | 6974 | | | | | red |

* Relative color, 1 is lightest, 5 is darkest.

Presence of solids may be due to a number of factors. Precipitate can form in unmodified initiator solution, especially if exposed to moisture.

NT=no test

Color development was not related to relative purity or initial color of the inhibitors used: HQ was in the form of pure white, needle-like crystals and THQ was in the form of a finely divided light colored powder. The MEHQ, in the form of 1 to 2 cm chunks with a definite tan to brown color, appeared less pure, but produced the least color in the initiator solutions.

Effect of Added MEHO on Cure Speeds and Film Properties

No significant effect on cure, either positive or negative, occurred with the addition of up to 1500 ppm MEHQ to the epoxide formulations evaluated.

A) Tests on Epoxy/Polyol Formulation

Two sets of panels were cured and evaluated to determine any trend in properties with regards to MEHQ content. All cured properties are within the margin of error of the tests. Tests were done using the following base formulation:

| Component | | % (Weight) |
|---|---|---|
| EEC | Cycloaliphatic epoxide | 80.53% |
| Union Carbide Tone 301 | Polycaprolactone triol | 18.95% |
| Silwet L-7602 | Surfactant | 0.53% |
| Initiator | Union Carbide UVI 6990 | 4.7-4.8% |

Viscosity: 346.0 cps @ 25° C. (4 spindle, 100 rpm)

Four levels of MEHQ were tested at one initiator concentration:

| % UVI 6990 * | ppm MEHQ |
|---|---|
| 4.67 | 1560 |
| 4.77 | 951 |
| 4.72 | 510 |
| 4.81 | 0 |

Desired MEHQ level was achieved by adding unmodified UVI 6990 in combination with UVI 6990 containing 6.42% MEHQ.

Run 1:

Experimental Conditions:

| Substrate | Aluminum Q panel |
|---|---|
| Film Application: | # 5 wire wound rods (film thickness 0.35 mil/9 |
| | micron) |
| Lamp: | One Fusion 300 watt/inch H bulb |
| Line Speed/Dose: | 90 fpm (27.4 m/min); 220 mJ/cm² |
| | 45 fpm (13.7 m/min); 410 mJ/cm² |
| Temperature: | 72° F./22° C. |
| Relative Humidity (%): | 37 |

TABLE D
Results: Post-Cured Properties

| | | | 90 fpm * | | 45 fpm * | |
|---|---|---|---|---|---|---|
| | % UVI | ppm | | Pencil | | Pencil |
| | 6990 * | MEHQ | MEK DR | Hardness | MEK DR | Hardness |
| D1 | 4.67 | 1560 | 52 | 2H | 79 | 2H |
| D2 | 4.77 | 951 | 60 | 4H | 83 | 4H |
| D3 | 4.72 | 510 | 56 | 4H | 57 | H |
| D4 | 4.81 | 0 | 49 | 4H | 60 | 3H |

* Median of 2 to 4 panels each, surface was tack-free after 5 seconds for all compositions Cured film properties were measured after post cure at room temperature.

Run 2:

Experiment Conditions

| Substrate | Aluminum Q panel |
|---|---|
| Film Application: | # 5 wire wound rods (film thickness 0.35 mil/9 |
| | micron) |
| Lamp: | One Fusion 300 watt/inch H bulb |
| Dose: | 192 mJ/cm² |
| Line Speed: | 100 fpm (30.5 m/min) |
| Temperature: | 73° F./22.5° C. |
| Relative Humidity (%): | 53 |

TABLE E
Results Cured Properties

| | | | One hour after Cure * | | Post Cured ** | |
|---|---|---|---|---|---|---|
| | % UVI | ppm | | Pencil | | Pencil |
| | 6990 * | MEHQ | MEK DR | Hardness | MEK DR | Hardness |
| E1 | 4.67 | 1560 | 15 | F | 22 | 4H |
| E2 | 4.77 | 951 | 17 | B | 14 | 6H |
| E3 | 4.72 | 510 | 17 | B | 20 | 6H |
| E4 | 4.81 | 0 | 15 | F | 20 | 4H |

* One panel.
* Median of 3 panels.

Surface was tack-free after 5 seconds for all compositions. Post-cured film properties, as reported on Tables D and E, were measured after post cure at room temperature in ambient conditions.

B) Tests on Epoxy Only Formulation

Following the tests of the epoxy/polyol formulations, formulations consisting of only initiator (2.9-3.0%), MEHQ and EEC were evaluated. No statistically significant differences in cured properties or cure speeds were detected for any composition tested, regardless of MEHQ level.

The following formulations were evaluated:

| | | % | ppm |
|---|---|---|---|
| Monomer | Initiator | Initiator | MEHQ |
| EEC | UVI 6990 | 2.96 | 0 |
| EEC | UVI 6990 | 2.96 | 510 |
| EEC | UVI 6990 | 2.90 | 1006 |
| EEC | Uvacure 1590 | 2.93 | 0 |
| EEC | Uvacure 1590 | 2.95 | 512 |
| EEC | Uvacure 1590 | 2.90 | 1012 |
| EEC | UVI 6990 | 2.96 | 500 |
| EEC | Uvacure 1590 | 2.97 | 500 |

Experimental Conditions:

| Substrate | Aluminum Q panel |
|---|---|
| Film Application: | # 5 wire wound rods (film thickness 0.35 mil/9 |
| | micron) |
| Lamp: | One Fusion 300 watt/inch H bulb |
| Dose: | 192 mJ/cm2 |
| Line Speed: | 30 fpm (30.5 m/min) |
| Temperature: | 72° F./22° C. |
| Relative Humidity (%): | 33 |

TABLE F
Results Cured Properties: For all compositions cured in
this series, properties after post cure were identical:

| | | | Ppm | Tack Free | | Pencil | Crosshatch |
|---|---|---|---|---|---|---|---|
| | Initiator | % Initiator | MEHQ | Time* | MEK DR | Hardness | Adhesion |
| F1 | UVI 6990 | 2.96 | 0 | 20 s | 200+ | 4H | <5% |
| F2 | UVI 6990 | 2.96 | 510 | 25 s | 200+ | 4H | <5% |

| | | | Ppm | Tack Free | | Pencil | Crosshatch |
|---|---|---|---|---|---|---|---|
| | Initiator | % Initiator | MEHQ | Time* | MEK DR | Hardness | Adhesion |
| F3 | UVI 6990 | 2.90 | 1006 | 15 s | 200+ | 4H | <5% |
| F4 | Uvacure 1590 | 2.93 | 0 | 20 s | 200+ | 4H | <5% |
| F5 | Uvacure 1590 | 2.95 | 512 | 25 s | 200+ | 4H | <5% |
| F6 | Uvacure 1590 | 2.90 | 1012 | 15 s | 200+ | 4H | <5% |
| F7 | UVI 6990 | 2.96 | 500 | 20 s | 200+ | 4H | <5% |
| F8 | Uvacure 1590 | 2.97 | 500 | 20 s | 200+ | 4H | <5% |

* Margin of error for tack-free time is ˜±5 seconds. Short tack-free times are better.

Effect of MEHQ on Odor Produced on Cure

Testing proved that the addition of MEHQ reduces the organosulfur/mercaptan/thio odor which develops during cure. Curing on a larger (commercial) scale will amplify the odor reduction effect.

The following formulations were evaluated for the effect on odor after cure:

| | | | % | ppm |
|---|---|---|---|---|
| | Composition | Initiator | Initiator | MEHQ |
| 1 | EEC | UVI 6990 | 3.0 | 0 |
| 2 | EEC | UVI 6990 | 3.0 | 0 |
| 3 | EEC | UVI 6990 | 3.0 | 0 |
| 4 | EEC | UVI 6990 | 3.0 | 0 |
| 5 | Base formulation * | UVI 6990 | 4.8 | 0 |
| 6 | Base formulation * | UVI 6990 | 4.8 | 0 |
| 7 | Base formulation * | UVI 6990 | 4.8 | 500 |
| 8 | EEC | UVI 6990 | 3.0 | 489 |
| 9 | EEC | UVI 6990 | 2.9 | 1006 |
| 10 | EEC | UVI 6990 | 3.0 | 510 |
| 11 | Base formulation * | UVI 6990 | 4.8 | 0 |
| 12 | EEC | UVI 6990 | 2.9 | 1006 |

* Base formulation contained 76.5 parts EEC, 18 parts Tone 301, 0.5 parts Silwet L-7602.

Experimental Conditions:

| Substrate | Aluminum Q panel |
|---|---|
| Film Application: | # 5 wire wound rods (film |
| | thickness 0.35 mil/9 micron) |
| Lamp: | Fusion 300 watt/inch H bulb |
| Dose: | 578 mJ/cm2 |
| Temperature: | 71° F./22° C. |
| Relative Humidity (%): | 30 |

Panels were placed into plastic jars ˜20 seconds after cure, the jars were sealed with tape, then placed in 60 ° C. oven overnight. The odor of two panels at a time were compared and ranked. In the majority of cases, addition of the quinone derivative reduced the odor of the cured panels.

TABLE G
Results: Odor of Cured Panels

| | Less Odor | | | | More Odor | | |
|---|---|---|---|---|---|---|---|
| | | % | | | | % | |
| | Compo- | Initi- | ppm | | Compo- | Initi- | ppm |
| | sition | ator | MEHQ | | sition | ator | MEHQ |
| G1 | EEC | 3.0 | 0 | < | Base | 4.8 | 0 |
| | | | | | formu- | | |
| | | | | | lation | | |
| G2 | EEC | 3.0 | 489 | < | EEC | 3.0 | 0 |
| G3 | EEC | 3.0 | 510 | < | EEC | 3.0 | 0 |
| G4 | EEC | 2.9 | 1006 | < | Base | 4.8 | 0 |
| | | | | | formu- | | |
| | | | | | lation | | |
| G5 | Base | 4.8 | 0 | ≈ | Base | 4.8 | 500 |
| | formu- | | | | formu- | | |
| | lation | | | | lation | | |
| G6 | EEC | 3.0 | 0 | ≈ | EEC | 2.9 | 1006 |

A second set of panels were cured and tested to confirm the previous results.

| | | % | ppm |
|---|---|---|---|
| Composition | Initiator | Initiator | MEHQ |
| EEC, surfactant * | Uvacure 1590 | 3.0 | 0 |
| EEC, surfactant * | Uvacure 1590 | 2.9 | 512 |
| EEC, surfactant * | Uvacure 1590 | 2.9 | 991 |
| EEC, surfactant * | Uvacure 1590 | 2.9 | 2009 |

* Composition was 99.5 parts EEC and 0.5 parts Silwet L-7602.

Experimental Conditions:

| Substrate | Aluminum Q panel |
|---|---|
| Film Application: | # 5 wire wound rods (film |
| | thickness 0.35 mil/9 micron) |
| Lamp: | Fusion 300 watt/inch H bulb |
| Dose: | 260 mJ/cm2 |
| Temperature: | 70° F./21° C. |
| Relative Humidity (%): | 50 |

TABLE H
Results: Odor of Cured Panels

| | |
|---|---|
| Less Odor | More Odor |

| | % | ppm | | % | ppm |
|---|---|---|---|---|---|
| | Initiator | MEHQ | | Initiator | MEHQ |
| H1 | 2.9 | 991 | < | 3.0 | 0 |
| H2 | 2.9 | 2009 | < | 2.9 | 512 |

The relative odor of cured panels was quantified in the following trial. No odor is classified as 0, and strong odor is classified as 5. As before, only two panels were evaluated at a time.

TABLE I
Results: Quantify Odor of Cured Panels

| | % | | | % | | |
|---|---|---|---|---|---|---|
| | Initi- | ppm | | Initi- | ppm | |
| | ator | MEHQ | odor | ator | MEHQ | odor |
| I1 | 3.0 | 512 | 1 | 3.0 | 0 | 5 |
| I2 | 2.9 | 991 | 3 | 2.9 | 2009 | 2 |
| I3 | 3.0 | 0 | 5 | 2.9 | 2009 | 1 |
| I4 | 2.9 | 512 | 2 | 2.9 | 991 | 4 |

From the above detailed specification and examples, it can be seen that the photopolymerizable composition of the present invention reduces the undesirable organosulfur/mercaptan/thio odor generated from the decomposed sulfonium salt released upon curing of sulfonium salt photoinitiator systems.

The foregoing description and examples of the present invention are merely illustrative thereof, and it is understood that other embodiments, variations and modifications can be effected without departing from the spirit or scope of the invention as set forth in the following claims.

1. A cationic photoinitiator composition for initiating cationic polymerization comprising:
a) a sulfur- or nitrogen-containing photoinitiator and
b) a deodorizing agent;
wherein the deodorizing agent reduces the odor of the photoinitiator composition upon initiation.

2. The composition of claim 1, wherein the photoinitiator is a sulfonium salt.

3. The composition of claim 1, wherein cationic polymerization of the composition is initiated by a member selected from the group consisting of ultraviolet, visible light, infrared, microwaves, radio, alpha, beta, gamma, X-rays and electron beams.

4. The composition of claim 1, wherein the deodorizing agent is a free radical inhibitor or a phenolic compound.

5. The composition of claim 4, wherein the phenolic compound is a quinone or a quinone derivative.

6. The composition of claim 5, wherein the quinone derivative is selected from the group consisting of hydroquinone, toluhydroquinone and methylhydroquinone.

7. The composition of claim 6, wherein the quinone derivative is methylhydroquinone.

8. The composition of claim 2, wherein the photoinitiator comprises an arylsulfonium salt or a phenacylsulfonium salt.

9. The composition of claim 8, wherein the arylsulfonium salt or phenacylsulfonium salt is selected from the group consisting of dialkylphenacylsulfonium salts, dialkyl-4-hydroxyphenylsulfonium salts, bis-p-diphenylsulfoniumphenylsulfide salts, diphenylphenylthiophenyl sulfonium salts, benzylsulfonium salts, benzyltetramethylene sulfonium salts, benzyl(p-hydroxyphenyl)methyl-sulfonium salts, triarylsulfonium salts, triphenylsulfonium salts and mixtures thereof.

10. The composition of claim 6, wherein the photoinitiator comprises an arylsulfonium salt or a phenacylsulfonium salt.

11. The composition of claim 10, wherein the arylsulfonium salt or phenacylsulfonium salt is selected from the group consisting of dialkylphenacylsulfonium salts, dialkyl-4-hydroxyphenylsulfonium salts, bis-p-diphenylsulfoniumphenylsulfide salts, diphenylphenylthiophenyl sulfonium salts, benzylsulfonium salts, benzyltetramethylene sulfonium salts, benzyl(p-hydroxyphenyl)methyl-sulfonium salts, triarylsulfonium salts, triphenylsulfonium salts and mixtures thereof

12. The composition of claim 1 further comprising a solvent.

13. The composition of claim 12, wherein said solvent is selected from the group consisting of propylene carbonate, y-butyrolactone, tetrahydrofuran, N,N-dimethylformamide, tetrahydropyran, aliphatic alcohols, aliphatic hydrocarbons, aromatic hydrocarbons, dioxane, dimethoxyethane, acetone, acetonitrile and mixtures thereof

14. The composition of claim 13, wherein the solvent is propylene carbonate or γ-butyrolactone.

15. A curable cationic polymerizable composition comprising:
a) a sulfonium salt photoinitiator,
b) polymerizable material, and
c) a deodorizing agent;
wherein the deodorizing agent reduces the odor of the composition upon initiation.

16. In a process for curing a cationic polymerizable composition containing:
a) a sulfonium salt photoinitiator and
b) polymerizable material;
the improvement which comprises adding a deodorizing agent to said composition in order to reduce the odor upon curing.

17. A photoresist composition comprising:
a photoactive sulfonium salt,
a resin binder and
a deodorizing agent;
wherein said deodorizing agent reduces the odor of the photoresist composition upon cure.

18. The photoresist composition of claim 17, wherein said composition is a chemically amplified positive-acting photoresist.

19. The photoresist composition of claim 17, wherein said composition is a negative-acting photoresist.

20. An article of manufacture having at least one surface, wherein said at least one surface comprises a coating layer of the photoresist composition of claim 17.

21. In a process for preparing a photoresist composition containing:
a) a photoactive sulfonium salt and
b) a resin binder;
the improvement which comprises adding a deodorizing agent to said photoresist composition in order to reduce the odor upon curing.

22. The process of claim 21, wherein said photoresist composition is a chemically amplified positive-acting photoresist composition.

23. The process of claim 21, wherein said photoresist composition is a negative-acting photoresist composition.
